(19) United States
(12) Patent Application Publication
(10) Pub. No.: US 2025/0364954 A1
(43) Pub. Date: Nov. 27, 2025

(54) AMPLIFIER

(71) Applicants: IMEC VZW, LEUVEN (BE); UNIVERSITEIT GENT, Gent (BE)

(72) Inventors: Michiel VAN OSTA, Schilde (BE); Guy TORFS, De Pinte (BE)

(21) Appl. No.: 18/874,089

(22) PCT Filed: Jun. 21, 2023
(86) PCT No.: PCT/EP2023/066735

§ 371 Date: Dec. 12, 2024

(30) Foreign Application Priority Data
Jun. 21, 2022 (EP) 22180098.0

(51) Int. Cl. H03F 1/02; H03F 3/24

(52) U.S. Cl. CPC H03F 1/0294; H03F 3/245; H03F 2200/331; H03F 2200/336

(57) ABSTRACT

An amplifier (100) is provided for amplifying a complex input communication signal (109) having an in-phase and quadrature component. The amplifier has a modulation circuitry (110) configured to convert the input signal to quantized samples (111) by performing oversampling, where the quantized samples represent a finite set of constellation points; and a phase mapping circuitry (120) configured to map the quantized samples onto two constant-envelope phase-modulated signals (121, 122) selected from a finite set of constant-envelope phase-modulated signals (172, 221-224) having a carrier frequency f_{c} (171) and (different) constant phases. A first and second power amplifier (130, 140) is configured to amplify the two constant-envelope phase-modulated signals by a gain G; and a combiner (150) is configured to combine the two amplified constant-envelope phase-modulated signals (131, 141) thereby obtaining a complex output communication signal (151) with the carrier frequency f_{c} representing an amplification (161) of the complex input communication signal (109).

### TECHNICAL FIELD

Various example embodiments relate to an amplifier for amplifying a complex input communication signal.

### BACKGROUND

An amplifier can be used in a transmitting circuitry to amplify an input communication signal to a powerful output signal for transmission by an antenna. Modern communication standards require linear power amplifiers because the signals have a high peak-to-average-power ratio, PAPR. These types of signals require the amplifier to operate with a power backoff to assure the linear amplification. This operation mode causes a decrease in overall power efficiency of the amplifier because amplifiers are typically most efficient near their saturation point.

An alternative to linear power amplifiers are switched-mode power amplifiers, SMPAs, because they have a theoretical efficiency of 100%. These SMPAs are however strongly non-linear such that they cannot be used for direct amplification of an amplitude modulated input signal. SMPAs are therefore used in combination with an additional conversion circuitry that converts the amplitude modulated signal to one or more constant-envelope signal for amplification by one or more SMPAs, and a reconstruction circuitry that reconstructs the amplified input signal from the amplified constant envelope signal.

Different solutions exist that allow using SMPAs for amplifying amplitude modulated signals. One solution is referred to as an outphasing architecture. With outphasing, the input signal is first converted into two phase modulated constant-envelope signals by a so-called signal component separator, SCS; the two signals are then amplified by two SMPAs; and the amplified signals are finally combined to obtain the amplified output signal. A problem with this solution is that the high peak-to-average power ratio signals still cause an efficiency loss because the efficiency of this solution decreases significantly with increasing outphasing angles of the SCS. Another problem of this solution is the sensitivity to amplitude and phase mismatch between the two outphasing branches and the complexity of the SCS.

Another solution is a cartesian sigma-delta based power amplifier. In this solution the input signal is first converted to a 1-bit binary signal by a sigma-delta modulator. This 1-bit and thus constant envelope signal is then amplified by an SMPA. Finally, the quantization noise is filtered out by a lowpass or bandpass filter. A disadvantage of this solution is the poor coding efficiency due to the sigma-modulator having only two quantization levels. A further problem is that the signal presented at the SMPA contains a significant amount of quantization noise which is also amplified by the SMPA resulting in a reduction of the overall efficiency.

### SUMMARY

The scope of protection sought for various embodiments of the invention is set out by the independent claims.

The embodiments and features described in this specification that do not fall within the scope of the independent claims, if any, are to be interpreted as examples useful for understanding various embodiments of the invention.

Amongst others, it is an object of embodiments of the invention to provide an amplifier that allows for a better efficiency and linearity.

This object is achieved, according to a first example aspect of the present disclosure, by an amplifier for amplifying a complex input communication signal having an in-phase and quadrature component; the amplifier further comprising:
a modulation circuitry configured to convert the input signal to quantized samples by performing oversampling, and wherein the quantized samples represent a finite set of constellation points;
a phase mapping circuitry configured to map the quantized samples onto two constant-envelope phase-modulated signals selected from a finite set of constant-envelope phase-modulated signals having a carrier frequency f_{c} and different constant phases;
a first and second power amplifier configured to amplify the two constant-envelope phase-modulated signals by a gain G;
a combiner configured to combine the two amplified constant-envelope phase-modulated signals thereby obtaining a complex output communication signal with the carrier frequency f_{c} representing an amplification of the complex input communication signal.

The input signal is a communication signal meaning that it contains information characterized by a certain signal bandwidth. The signal may for example correspond to a sequence of time domain symbols each carrying a certain amount of data. The modulation circuitry outputs samples at an oversampling frequency. Each sample comprises a quantization of the in-phase and quadrature component of the input signal and may be represented by two binary numbers having a number of bits according to the applied quantization. As such, each quantized sample can be represented as a select one of a finite set of constellation points. In other words, the quantized samples also comprise an in-phase and quadrature component that represent the finite set of constellation points. Oversampling refers to the rate of the quantized samples with respect to the bandwidth of the communication signal, more specifically that the sampling rate is higher than the Nyquist rate, i.e. two times the bandwidth. The input signal may take the form of a digital input signal represented by a discrete stream of binary values or by an analogue signal. The phase mapping circuitry then represents each quantized sample as a combination of two constant-envelope phase-modulated signals, i.e. two phasors of which the sum forms the constellation point represented by the quantized sample. In other words, for a certain quantized sample, the phase mapping circuitry selects the two phasors such that a combination of two phasors represents that quantized sample. As there are a limited set of possible constellation points, all these points can be represented by a finite set of such combinations. The output of the phase mapping circuitry is a pair of such phasors with carrier frequency f_{c}. The output of the phase mapping circuitry can then change to different phasors at the oversampling frequency according to the quantization result. The two selected phasors are then each amplified by the power amplifiers with the same gain and combined again to produce the complex output communication signal at the carrier frequency f_{c}. For the power amplification,

The claimed amplifier has different advantages. First, non-linear power amplifiers such as for example switched-mode power amplifiers, SMPAs, can still be used as amplifier as the output of the phase mapping circuitry is a phasor thereby benefitting from the high efficiency. Second, the complexity of a signal component separator, SCS, is avoided by the use of the modulation and phase mapping circuitry. As such, no complex non-linear computations are needed resulting in a lower power consumption. Third, by the use of a limited number of fixed phasors, there is no need for complex phase-modulation circuitry through various delay elements further resulting in a reduced power consumption. Fourth, by quantizing to phases instead of to amplitude, it is possible to have more quantization levels while the signals applied to the amplifiers exhibit lower quantization noise than the 1-bit quantization signals in a cartesian delta-sigma based power amplifier. This results in a much more efficient use of the amplifier.

According to example embodiments the modulation circuitry corresponds to a sigma delta modulator. As both the in-phase and quadrature component of the signal are modulated, the modulator can also be referred to as a complex sigma delta modulator.

According to example embodiments the amplifier further comprises a bandpass filter operable around the carrier frequency f_{c} and configured to filter out quantization noise introduced by the modulation circuitry from the complex output communication signal thereby obtaining a filtered complex output communication signal. This results in reduced quantization noise at the output thereby improving the spectral mask of the transmitted signal.

The complex input communication signal may be a digital or analogue communication signal. In case of an analogue communication signal, the modulation circuitry performs an oversampling analogue-to-digital conversion. In case of a digital communication signal, the modulation circuitry will increase the sampling frequency of the input signal and lower the resolution, i.e. number of bits, according to the quantization.

The complex communication signal may correspond to a baseband signal, i.e. a signal that is not modulated onto a higher frequency carrier. The signal may also be modulated onto an intermediate frequency, IF. In both cases the amplifier also functions as an upmixing amplifier which, apart from amplifying the signal, also modulates it onto the carrier frequency f_{c}.

According to example embodiments, the phase mapping circuitry is configured to perform a one-to-one mapping between the finite set of constellation points and pairs of the finite set of constant-envelope phase-modulated signals. In other words, a certain constellation point is always mapped to the same combination of phasors. This allows for a simple and straightforward implementation, for example by a multiplexer that selects the phasors by the quantized samples.

According to example embodiments, the phase mapping circuitry is configured to map at least one constellation point to a select one of different possible pairs of the finite set of constant-envelope phase-modulated signals, and to select the select one such that additional signal transitions in the two constant-envelope phase-modulated signals are minimized.

It may be possible to map one constellation point to different combinations of phasors. By selecting the combination that results in the least signal transitions the amplifier will operate more efficiently and with less distortion.

According to further example embodiments the phase mapping circuitry is further configured to perform the mapping in alignment with the carrier frequency f_{c} such that no additional transition occurs in between edges of the constant-envelope phase-modulated signals.

The phasors are signals oscillating at the carrier frequency f_{c} and the selected phasor can change according to the oversampling frequency. By aligning the phasor changes with the oscillations, the amounts of signal transitions can be further reduced, again resulting in a more efficient use of the amplifier.

According to example embodiments the amplifier comprises a clock generator for generating a signal at the carrier frequency f_{c} to derive the finite set of constant-envelope phase-modulated signals, and a clock division circuitry configured to generate a clock signal for performing the oversampling by dividing the generated signal. By deriving the clock for the oversampling from the generated carrier frequency f_{c} synchronization between the different clocks is guaranteed and transitions can be optimized.

According to example embodiments the modulation circuitry is further configured to account for a quantization offset when performing the conversion so as to compensate for a gain or phase mismatch between the first and second amplifier. In other words, a mismatch in the first and second amplifier can be easily corrected by adapting the quantization in the modulation circuitry. This results in a calibration that doesn't require additional circuitry but merely a change in the applied quantization levels. By such adaptation, the obtained phasors will compensate for the gain or phase mismatch in the subsequent circuitries of the amplifier.

According to a further example embodiment, the combiner is a Chireix non-isolated combiner.

According to example embodiments, the finite set of constant-envelope phase-modulated signals have four phases and the modulation circuitry comprises a three-level quantizer for deriving nine constellation points. With four different phasors, all nine constellation points can be represented. Furthermore, four phasors with a 90 degrees phase shift can be created from a single quadrature oscillator having differential outputs.

According to another example aspect, the present disclosure relates to an integrated circuitry comprising the amplifier according to the first example aspect.

According to another example aspect, the present disclosure relates to a method for determining the quantization offset in the amplifier according to the first aspect when the combiner is a Chireix non-isolated combiner; the method comprises the following steps:
selecting different combinations of the constant-envelope phase-modulated signals;
measuring an output power of the amplifier when applying the selected different combinations;
estimating therefrom the gain mismatch and phase mismatch between the first and second power amplifiers;
using the gain mismatch and phase mismatch, calculating the output power of the respective the first and second power amplifiers for the selected different combinations;
using the calculated output power, determining actual constellation points associated with the selected different combinations;
deriving the quantization offset from the difference in the actual constellation points and the finite set of constellation points.

According to another example aspect, the present disclosure relates to a method for amplifying a complex input communication signal having an in-phase and quadrature component further comprising:
converting the input signal to quantized samples by performing oversampling, and wherein the quantized samples represent a finite set of constellation points;
mapping the quantized samples onto two constant-envelope phase-modulated signals selected from a finite set of constant-envelope phase-modulated signals having a carrier frequency f_{c} and different constant phases;
amplifying the two constant-envelope phase-modulated signals by a gain G;
combining the two amplified constant-envelope phase-modulated signals thereby obtaining a complex output communication signal with the carrier frequency f_{c} representing an amplification of the complex input communication signal.

### BRIEF DESCRIPTION OF THE DRAWINGS

Some example embodiments will now be described with reference to the accompanying drawings.

FIG. 1 shows an example embodiment of an amplifier;

FIG. 2 shows a constellation diagram with constellation points and phasors in an amplifier according to an example embodiment;

FIG. 3 shows a phase mapping circuitry of an amplifier according to an example embodiment;

FIG. 4 shows phasors aligned with a sampling signal in an amplifier according to an example embodiment;

FIG. 5 shows transitions between different phasors according to an example embodiment;

FIG. 6 shows a constellation diagram with ideal quantization samples and with compensated quantization samples incorporating mismatch according to an example embodiment;

FIG. 7 shows a constellation diagram with ideal quantization samples and with compensated quantization samples incorporating mismatch according to an example embodiment;

FIG. 8 shows a complex delta-sigma modulation circuitry of an amplifier according to an example embodiment; and

FIG. 9 illustrates an equivalent circuit of a Chireix non-isolated power combiner according to an example embodiment.

### DETAILED DESCRIPTION OF EMBODIMENT(S)

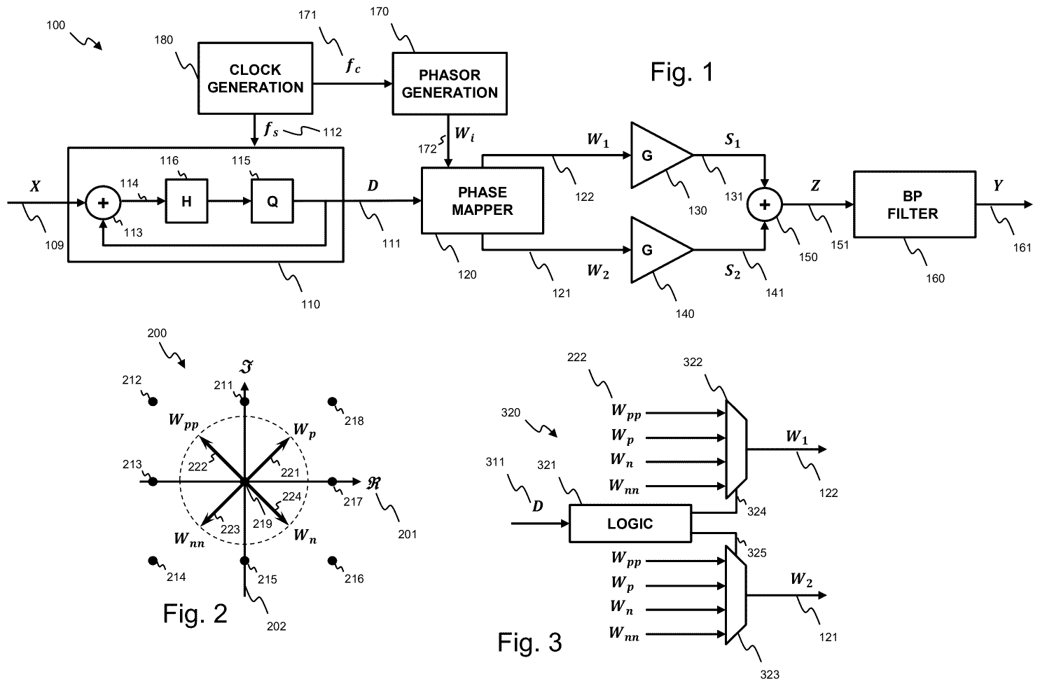

FIG. 1 illustrates functional blocks of an amplifier 100 circuitry for amplifying a complex input communication signal 109 to a complex output communication signal 151 or to a filtered complex output communication signal 161. Amplifier 100 may for example be connected to an antenna for transmitting the amplified signal wirelessly or to a wireline transmitter for transmitting the amplified signal onto a wireline medium.

Amplifier 100 may be used as a power amplifier, PA, to amplify a communication signal to a more powerful signal for a transmit antenna. Amplifier 100 is particularly suited for the amplification of communication signals that have a high Peak-to-Average-Power Ratio, PAPR. Such signal are found in a variety of modern telecommunication standards that use complex modulation techniques such as orthogonal frequency-division multiplexing, OFDM. In such applications, the power amplifier may be a dominant factor in a radio's power efficiency.

Input signal 109 is a communication signal carrying information having a certain information bandwidth. Signal 109 is represented by an in-phase, I, and quadrature, Q, signal component. Input signal 109 may correspond to a baseband communication signal wherein the signal bandwidth is substantially the same as the information bandwidth. Input signal 109 may also correspond to a signal that is modulated onto an intermediate frequency, IF, wherein the information bandwidth is centred around this intermediate frequency. Input signal 109 can correspond to an analogue communication signal wherein the I- and Q component have a continuous time varying amplitude. Input signal 109 can also corresponds to a digital communication signal represented by a sequence of discrete amplitude values, for example as a series of binary numbers at a certain input or sampling rate. The I- and Q-component can be represented by two separate binary numbers or by a single binary number. A complex digital input signal 109 can then be characterized by a sample rate and a resolution.

Amplifier 100 comprises a modulation circuitry 110 that converts the complex input communication signal 109 to quantized samples 111. The output is created according to a certain sampling rate or frequency 112 defining the rate at which the quantized samples 111 are output by circuitry 110. Circuitry 110 performs the quantization according to a certain predetermined resolution, e.g. 2-bit, 4-bit etc, such that the input signal 109 can be reconstructed from the output signal 111 within a certain accuracy. Modulation circuitry 110 performs an oversampling of the input signal 109. Oversampling refers to the rate of the quantized samples with respect to the bandwidth of the input communication signal, more specifically that the sampling rate 112 is higher than the Nyquist rate, i.e. two times the bandwidth of the input signal 109. By the oversampling, the resolution of the quantized samples 111 at the output will be lower than the resolution of the input signal 109. For example, an oversampling rate up to ten may be selected.

One example of an oversampling modulation circuitry 110 is a delta-sigma modulator or shortly ΔΣ-modulator. The main functional blocks of a delta-sigma modulator are as also depicted in FIG. 1. In a summation circuitry 113 of ΔΣ-modulator 110, the difference is taken between the input signal 109 and the quantized output sample 111 thereby obtaining a difference value 114. The difference value then first passes through a loop filter 116 that defines the noise shaping. The filtered value is then quantized by the quantizer 115 thereby obtaining the quantized output 111. The output 111 is then fed back to serve as input for summation circuitry 113. If the input signal 109 is an analogue signal, then the feedback loop further comprises a digital-to-analogue conversion circuitry for converting the output sample 111 to an analogue value. It will be understood to the skilled person that any known ΔΣ-modulator 110 may be selected according to required input bandwidth, the type of the input sample 109, the oversampling rate 112 and quantization levels of the quantizer.

The I- and Q-component of the quantized output samples 111 can be represented as constellation points in a constellation diagram. FIG. 2 shows an example of such a constellation diagram 200 having nine constellation points 211 to 219. Both the I- and Q-component can take three values, i.e. 3 bits, on respectively the real axis 201 and Imaginary axis 202 of the diagram 200. As such, a finite set of nine different constellation points can be derived from the quantized samples 111.

The amplifier further comprises a phase mapping circuitry 120 configured to output two phasors 121, 122 based on the quantized input sample 111. The phasors are selected from a set of phasors 172 generated by a phasor generation circuitry 170. Each phasor 172 is a signal oscillating with a same constant carrier frequency 171, having a same constant envelope or amplitude, and having a different constant phase. The set of different constant phases and thus the set of phasors is selected such that each quantized sample represented in the constellation diagram can be represented by a combination of two of the phasors. The output phasors 121, 122 are then selected by the phase mapping circuitry such that the combination represents the input quantized sample 111.

An example set of four phasors 221 to 224 is shown in the constellation diagram 200 of FIG. 2. Phasor 221 has a 45 degrees or π/4 rad phase, phasor 222 has a 135 degrees or 3π/4 rad phase, phasor 223 has a 225 degrees or −3π/4 rad phase and phasor 224 has a 315 degrees or −π/4 rad phase. Each constellation point 211-219 can then be composed by a combination of two phasors: point 211 as the combination of phasors 221 and 222; point 212 as two times phasor 222; point 213 as the combination of phasors 222 and 223; point 214 as two times phasor 223; point 215 as the combination of phasors 223 and 224; point 216 as two times phasor 224; point 217 as the combination of 224 and 221; point 218 as two times 221; and point 219 as the combination of 221 and 223 or as the combination of 222 and 224.

For the constellation 200, phasor generation circuitry 170 has to generate four phasors. According to an example embodiment, phasor generation circuitry 170 comprises an oscillator that oscillates at the carrier frequency having a differential output. From such differential output two phasors in anti-phase can be obtained by reverting the wiring order. For example, the clock may generate phasor 221 and by reverting the wiring order phasor 223 is obtained. Phasor generation circuitry 170 may then further comprise a quadrature modulator that provides phasors 222 and 219 from the generated phases 221 and 223.

FIG. 3 shows an example embodiment of a phase mapping circuitry 320 for the mapping of the constellation points of diagram 200 onto the phasors 221-224. Circuitry 320 comprises a first selector circuitry 322 configured to select one of the phasors 221-224 for the output 122 based on a first input control signal 324. Circuitry 320 further comprises a second selector circuitry 323 configured to select one of the phasors 221-224 for the output 121 based on a second input control signal 325. Both control signals 324 and 325 are generated by a logic circuitry 321 that performs a one-to-one mapping between the quantized input sample 311 and a corresponding pair of phasors 221-224 according to the corresponding control signals 324, 325. In other words, based on the input 311 the logic function of logic circuitry 321 determines two-bit control signals 324, 325 for the multiplexers 322, 323 thereby selecting the phase-shifted carriers 121, 122. Alternatively, logic circuitry 321 may also comprise a lookup table providing the logic signals 324, 325 for each possible input 311.

As the quantized samples 111 will be updated at the oversampling frequency 171, also the output phasors 121, 122 can change phase at the same oversampling frequency. This mapped output phasors 121, 122 are then amplified by first and second power amplifiers 130 and 140 having an equal gain G. Amplifiers 130, 140 may be non-linear amplifiers, for example switched-mode power amplifiers, SMPAs. SMPAs are known in the art to achieve a theoretical efficiency of 100%. The outputs 131, 141 of respective amplifiers 130, 140 then produces a non-linear amplification of input phasors 122, 121. The two amplified phasors 131, 141 are then combined in a combiner circuitry 150 thereby obtaining the complex output communication signal 151. Such combiner circuitries are well known in the art and may be made with lumped (R)LC components, transmission lines, transformers, or combinations thereof. One example of a combiner is a Wilkinson combiner using transmission lines and resistors. Another example of a combiner is the Chireix combiner network which is a non-isolating combiner resulting in load modulation. Circuitry 150 is also referred to as a power combiner in the art. According to an embodiment, circuitry 150 may correspond to a lossless, or non-isolated, power combiner, resulting in load modulation. Output signal 151 then characterizes an amplified version of the input communication signal 109 upsampled to the carrier frequency f_{c}. As such, amplifier 100 can operate as an upsampling power amplifier 100.

Optionally, amplifier 100 may comprise a filter circuitry 160 that filters out unwanted noise from the amplified signal 151 around the information bandwidth at the carrier frequency 171. In other words, filter circuitry 160 can correspond to a bandpass filter around the carrier frequency 171. By the oversampling modulation circuitry 110, quantization noise will be introduced and shaped out of the information band. As a result, most of this introduced quantization noise can be removed by bandpass filter 160.

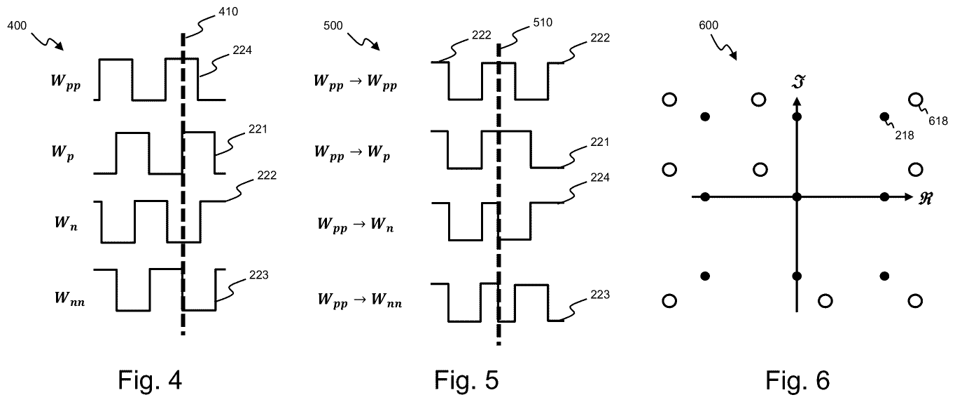

Both phasors 121 and 122 can change phase according to the phase mapping circuitry 120 at the rate of the oversampling frequency 112. At each transition of the oversampling clock 112 a change between the phasors 172 can occur. Such transition may occur within each phase of the phasor, e.g. during a transition or edge of the phasor oscillation or when the phasor is at its maximum or minimum. Advantageously, the mapping performed by the phase mapping circuitry 120 is performed in alignment with the carrier frequency f_{c} 171 such that a minimum amount of additional transitions occur in between edges of the constant-envelope phase-modulated signals. FIG. 4 illustrates such alignment for the example illustrated in FIG. 2 and FIG. 3 where there are four phasors 221-224 with a 90 degrees phase difference. The vertical dashed line 410 illustrates the edge of the oversampling clock 112 that is in alignment with the four phasors 221-224. During the edge 410 of the oversampling clock phasor 224 is always at its maximum, phasor 221 is on a rising edge, phasor 222 is at its minimum, and phasor 223 is on a falling edge. By this alignment phasors 221, 223 will either remain at their current value or transition to the opposite value. As the alignment minimizes additional transitions and short spikes, the amplifier 100 will have a more linear behaviour. Further, when using switched-mode power amplifiers 130, 140, such alignment will result in better power efficiency.

It may occur that there is more than one possibility for mapping a quantized sample by the phase mapping circuitry 120. For example, phasors 121 and 122 can always be swapped in the example depicted in FIG. 2. This introduces an extra degree of freedom that may be exploited. As such, according to an example embodiment the phase mapping circuitry 120 can be configured to map at least one constellation point to a select one of different possible pairs of the finite set of constant-envelope phase-modulated signals. From these possible pairs, the one is then selected such that additional signal transitions in the signals 121 and 122 are minimized. This mapping may be achieved by replacing the logic circuitry 321 of FIG. 3 with a state machine. The phase mapping circuitry 120 then selects the phasor combination 121, 122 based on the current quantization point 311 and the previous phasor combination 121, 122. As a result, the next phasor combination can be chosen such that additional signal transitions in the outphasing signals are minimized. This principle is shown in FIG. 5 for transitions 500 from phasor 222 to each one of phasors 221-224 upon a transition 510. A transition from phasor 222 to 222 does not cause the multiplexer 322, 323 to change its output and, thus, no additional switching occurs. In case of the transition from phasor 222 to 224 the output of the multiplexer will switch to a low value after a quarter of a clock period. A similar behaviour occurs when transitioning from phasor 222 to 223 with the difference that phasor 223 comes back high a quarter period after the clock. As a result, two quarter period pulses occur. Lastly, the transition from phasor 222 to 221 shows that the next signal transition is delayed by a quarter period. For transitions 500, the transition to 223 is considered the worse because of the two shorter pulses, then transition to 224 because of the single shorter pulse, then the transition to 221 with the longer pulse. The transition to 222 does not have a negative impact because no switching occurs. It should be noted that the transition to 221 is considered to have a penalty because an actual circuitry implementation the waveforms will not have a zero rise and fall time. In such case, the transition to 221 will the waveform of phasor 221 will still be rising towards a high value during the transition 510. As a result, an incomplete transition may still be observable at the multiplexer output. When selecting a new combination of phasor pairs, the state machine will select the pairs such that the penalty of additional transitions is minimized.

Amplifier 100 comprises two clocks, a first clock oscillating at the oversampling frequency 112 and a second clock oscillating at the carrier frequency 171. Such clocks may be generated by clock generation circuitry 180. According to an example embodiment the clock generator 180 generates the clock signal at the carrier frequency f_{c} 171 for deriving the phasors 170. The clock generator further comprises a clock division circuitry (not shown in FIG. 1) that is configured to generate the clock signal oscillating at the oversampling frequency 112 by dividing the generated signal clock signal at the carrier frequency f_{c} 171. As a result, the edges of the oversampling signal will have a predetermined relation with respect to the edges of the phasors 172. This makes the alignment between the signals easy to implement and avoids drift between the signals. According to a further embodiment, clock generator 180 comprises a sequency of divide by two clock division block such that fₛ=m·f_{c} with m=½ⁿ and n∈ [symbol] .

Amplifiers 130, 140 may exhibit gain or phase mismatch, or imbalance, i.e. there may be a small unwanted difference in gain between the amplifiers, or the amplifiers may introduce different phase shifts. These mismatches will cause non-linearities in the resulting amplified signal 151. According to an example embodiment the modulation circuitry is configured to apply a quantization offset when performing the conversion so as to compensate for such a gain or phase mismatch between the first and second amplifier. Such mismatch compensation is illustrated in the constellation diagram 600 of FIG. 6 for the same situation as FIG. 2 where the quantization is performed into nine constellation points 211-219. The solid dots illustrate the constellation points obtained at the output of amplifier 100 without mismatch and the circled dots illustrate the case where there is gain mismatch. For example, constellation point 218 may be shifted to constellation point 618 by a gain mismatch between the amplifiers. This shift can be compensated for by selecting a quantization offset in the quantizer 115 such that, by the compensation, the obtained phasors will compensate for the gain or phase mismatch in the subsequent circuitries of the amplifier. These quantization offsets may be obtained during a calibration procedure wherein the gain and phase mismatch of the amplifiers 130 and 140 is measured and quantization offsets are determined to compensate for the mismatch.

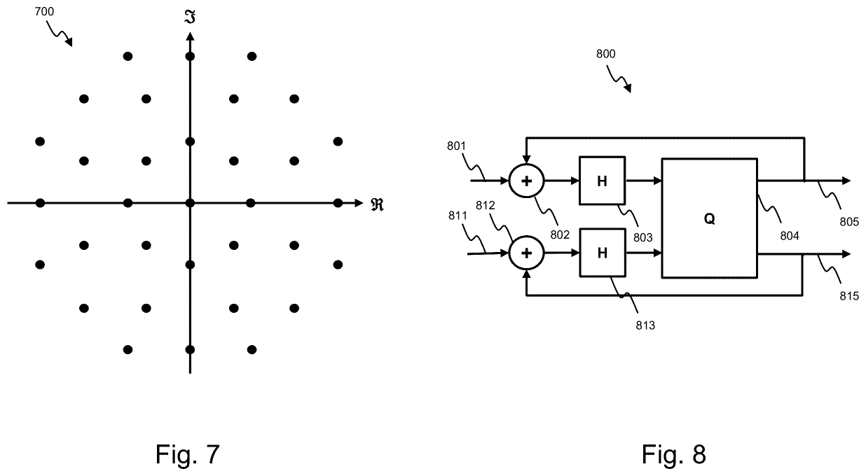

FIG. 2 to FIG. 6 illustrate the operation of amplifier 100 for a quantization to nine constellations points 211-219 and the mapping to pairs of four different phasors 221-224. The operation of amplifier 100 may be extended to different constellations, for example by introducing more quantization levels and thus more constellations points. Increasing the number of constellation points leads to an increased efficiency of the modulation circuitry 110 in terms of both coding efficiency and signal-to-noise-and-distortion ratio, SNDR. This also requires a larger set of phasors 172 such that all constellation points can be generated. FIG. 7 illustrates a constellation diagram 700 that can be constructed from 8 phasors having a phase ϕ=π/8+n π/4 rad with n={0, 1, . . . , 7}. For constellation diagram 700, there are four quantization levels needed in the quantizer 115 for both the I- and Q-component. Further, only a subset of the quantization points in diagram 700 may be used to obtain orthogonal decision levels allowing independent quantization of the I and Q components.

FIG. 8 illustrates a modulation circuitry 800 for use in amplifier 100. Input signal 801 is an in-phase component of input communication signal 109 and input signal 811 is quadrature component of input communication signal 109. At summation circuitries 802, 812, the difference between the input signals 801, 811 and respective quantized output samples 805, 815 is taken. These differences are further integrated or filtered by respective integrator or loop filter circuitries 803, 813 to control the shape of the quantization noise. The resulting integrated values are then quantized by quantizer 804 according to predetermined quantization levels according to the applied constellation diagram, e.g. as depicted in FIGS. 2, 6 and 7. The so-obtained output samples 805, 815 then determine the in-phase and quadrature phase component of the constellations points in the constellation diagram and serve as input for phase mapper 120.

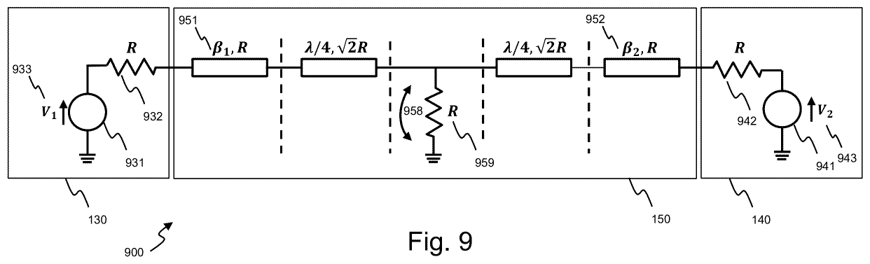

According to an example embodiment, combiner circuitry 150 corresponds to a Chireix non-isolated combiner as known in the art. FIG. 9 illustrates an equivalent circuit 900 of such combiner circuitry 150 and power amplifiers 130 and 140. Power amplifier 130 can be represented by a voltage source 931 and its output resistance 932 with value R. Power amplifier 140 can be represented by a voltage source 941 and its output resistance 942, also with value R. The voltage 933 generated by voltage source 931 then represents the amplified phasor 131 and may be mathematically represented as V₁=α e^{jϕ}^{₁} wherein α is the amplification and ϕ₁ is the phase of the phasor 131. Similarly, voltage 943 generated by voltage source 941 then represents the amplified phasor 141 and may be mathematically represented as V₂=(α+Δα) e^{jϕ}^{₂} wherein Δα represents the amplification imbalance or mismatch between amplifiers 931 and 941 and ϕ₂ is the phase of the phasor 141. Phase or delay mismatch may be represented by different delays β₁ and β₂, indicated in FIG. 9 by respective reference signs 951 and 952.

The use of a Chireix non-isolated combiner has the advantage that mismatch compensation as described with reference to FIG. 6 may be determined by power measurements of the combiner's output as will now be explained.

Amplifiers 130 and 140 both contribute to the voltage V_{L} (958) over the load R (959). The contribution V_{L,i} of an amplifier may be described as:

$${V}_{L , i} = - j \frac{\sqrt{2}}{4} {e}^{- j {β}_{i}} {V}_{i} \qquad ( Eq . 1 )$$

wherein i=1 for amplifier 130 and i=2 for amplifier 140. The total voltage V_{L} (958) may then be described by the following formula:

$${V}_{L} = {V}_{L , 1} + {V}_{L , 2} \qquad ( Eq . 2 )$$

$${V}_{L} = - j α \frac{\sqrt{2}}{4} {e}^{- j {β}_{1}} {e}^{j {ϕ}_{1}} + - j ( α + Δα ) \frac{\sqrt{2}}{4} {e}^{- j {β}_{2}} {e}^{j {ϕ}_{2}} \qquad ( Eq . 3 )$$

The total power P_{L} delivered to the load 959 is then:

$${P}_{L} = \frac{{\vert {V}_{L} \vert}^{2}}{2 R} \qquad ( Eq . 4 )$$

This total power P_{L} may be measured for different sets of the phasors ϕ₁ and ϕ₂. Based on these measurements the parameters α, Δα. β₁ and β₂ may be fitted, e.g. in a least square manner. Using the so-obtained parameters, the output power of the two amplifiers 130, 140 may be calculated for different sets of phasers ϕ₁ and ϕ₂ using the above equations. These calculated output powers may then be used for representing the constellation points that would be realized with these outphasing angles. The so-obtained constellation points then define the quantization offsets as described with reference to FIG. 6 for performing the mismatch compensation.

According to an embodiment the following steps are performed for calibrating amplifier 100 with a Chireix non-isolated combiner circuitry 150 as illustrated and described with reference to FIG. 9. According to a first step, different combinations of phasors are selected according to an applicable constellation diagram, e.g. combinations of phasors 221-224 defining constellation points 211-219. For each set of phasors the total power delivered at the output of the combiner 150 is measured thereby obtaining a set of power measurements associated with the respective constellations points. Referring back to Eq. 3 and Eq. 4, the power measurements provide different values of P_{L} for different values of ϕ₁ and ϕ₂. Then, according to a second step, the values for α, Δα, β₁ and β₂ are estimated based on Eq. 3 and Eq. 4 and the measured relation between the different values of P_{L} and the different combinations of phasors ϕ₁ and ϕ₂. Then, according to a third step, the power at the output of each amplifier 130, and 140 is determined by application of Eq. 1 thereby obtaining two power values per set of phasors ϕ₁ and ϕ₂. Then, according to a fourth step, the power values are used as the coordinates for the actual constellation points in the constellation diagram thereby obtaining the actual constellation points 618 such as shown with reference to FIG. 6. In the last step, the difference between the constellation points 218 and 618 is used to determine the quantization offset.

Amplifier 100 may be part of an integrated circuit construed on a semiconductor material using a semiconductor fabrication process. Amplifier 100 may also be constructed by separate discrete components each performing part of the above-described functions.

As used in this application, the term “circuitry” may refer to one or more or all of the following:
(a) hardware-only circuit implementations such as implementations in only analogue and/or digital circuitry and
(b) combinations of hardware circuits and software, such as (as applicable):
   (i) a combination of analogue and/or digital hardware circuit(s) with software/firmware and
   (ii) any portions of hardware processor(s) with software (including digital signal processor(s)), software, and memory(ies) that work together to cause an apparatus, such as a mobile phone or server, to perform various functions) and
(c) hardware circuit(s) and/or processor(s), such as microprocessor(s) or a portion of a microprocessor(s), that requires software (e.g. firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in a server, a cellular network device, or other computing or network device.

Although the present invention has been illustrated by reference to specific embodiments, it will be apparent to those skilled in the art that the invention is not limited to the details of the foregoing illustrative embodiments, and that the present invention may be embodied with various changes and modifications without departing from the scope thereof. The present embodiments are therefore to be considered in all respects as illustrative and not restrictive, the scope of the invention being indicated by the appended claims rather than by the foregoing description, and all changes which come within the scope of the claims are therefore intended to be embraced therein.

It will furthermore be understood by the reader of this patent application that the words “comprising” or “comprise” do not exclude other elements or steps, that the words “a” or “an” do not exclude a plurality, and that a single element, such as a computer system, a processor, or another integrated unit may fulfil the functions of several means recited in the claims. Any reference signs in the claims shall not be construed as limiting the respective claims concerned. The terms “first”, “second”, third”, “a”, “b”, “c”, and the like, when used in the description or in the claims are introduced to distinguish between similar elements or steps and are not necessarily describing a sequential or chronological order. Similarly, the terms “top”, “bottom”, “over”, “under”, and the like are introduced for descriptive purposes and not necessarily to denote relative positions. It is to be understood that the terms so used are interchangeable under appropriate circumstances and embodiments of the invention are capable of operating according to the present invention in other sequences, or in orientations different from the one(s) described or illustrated above.

1. An amplifier for amplifying a complex input communication signal having an in-phase and quadrature component comprising:
a modulation circuitry configured to convert the input signal to quantized samples by performing oversampling, and wherein the quantized samples comprise an in-phase and quadrature component representing a finite set of constellation points;
a phase mapping circuitry configured to map the quantized samples onto two constant-envelope phase-modulated signals selected from a finite set of constant-envelope phase-modulated signals having a carrier frequency f_{c} and different constant phases; and wherein the two constant-envelope phase-modulated signals are selected such that a combination of the two constant-envelope phase-modulated signals represents the respective quantized samples;
a first and second power amplifier configured to amplify the two constant-envelope phase-modulated signals by a gain G;
a combiner configured to combine the two amplified constant-envelope phase-modulated signals thereby obtaining a complex output communication signal with the carrier frequency f_{c} representing an amplification of the complex input communication signal.

2. The amplifier according to claim 1 wherein the modulation circuitry is a sigma delta modulator.

3. The amplifier according to claim 1 further comprising a bandpass filter operable around the carrier frequency f_{c} and configured to filter out quantization noise introduced by the modulation circuitry from the complex output communication signal thereby obtaining a filtered complex output communication signal.

4. The amplifier according to claim 1 wherein the complex input communication signal is a digital or analogue communication signal.

5. The amplifier according to claim 1 wherein the complex input communication signal is a baseband signal or a signal modulated onto an intermediate frequency, IF, thereby obtaining an upmixing amplifier.

6. The amplifier according to claim 1 wherein the phase mapping circuitry is configured to perform a one-to-one mapping between the finite set of constellation points and pairs of the finite set of constant-envelope phase-modulated signals.

7. The amplifier according to claim 1 wherein the phase mapping circuitry is configured to map at least one constellation point to a select one of different possible pairs of the finite set of constant-envelope phase-modulated signals, and to select the select one such that additional signal transitions in the two constant-envelope phase-modulated signals are minimized.

8. The amplifier according to claim 1 wherein the phase mapping circuitry is further configured to perform the mapping in alignment with the carrier frequency f_{c} such that no additional transition occurs in between edges of the constant-envelope phase-modulated signals.

9. The amplifier according to claim 1 further comprising a clock generator for generating a signal at the carrier frequency f_{c} to derive the finite set of constant-envelope phase-modulated signals, and a clock division circuitry configured to generate a clock signal for performing the oversampling delta modulation by dividing the generated signal.

10. The amplifier according to claim 1 wherein the modulation circuitry is further configured to account for a quantization offset when performing the conversion so as to compensate for a gain or phase mismatch between the first and second amplifier.

11. The amplifier according to claim 10 wherein the combiner is a Chireix non-isolated combiner.

12. The amplifier according to claim 1 wherein the finite set of constant-envelope phase-modulated signals has four phases, and the modulation circuitry comprises a three-level quantizer for deriving nine constellation points.

13. An integrated circuitry comprising the amplifier according to claim 1.

14. A method for determining the quantization offset in the amplifier according to claim 11, the method comprising the following steps:
selecting different combinations of the constant-envelope phase-modulated signals;
measuring an output power of the amplifier when applying the selected different combinations;
estimating therefrom the gain mismatch and phase mismatch between the first and second power amplifiers;
using the gain mismatch and phase mismatch, calculating the output power of the respective the first and second power amplifiers for the selected different combinations;
using the calculated output power, determining actual constellation points associated with the selected different combinations; and
deriving the quantization offset from the difference in the actual constellation points and the finite set of constellation points.

15. A method for amplifying a complex input communication signal having an in-phase and quadrature component comprising:
converting the input signal to quantized samples by performing oversampling, and wherein the quantized samples represent a finite set of constellation points;
mapping the quantized samples onto two constant-envelope phase-modulated signals selected from a finite set of constant-envelope phase-modulated signals having a carrier frequency f_{c} and (different) constant phases;
amplifying the two constant-envelope phase-modulated signals by a gain G; and
combining the two amplified constant-envelope phase-modulated signals thereby obtaining a complex output communication signal with the carrier frequency f_{c} representing an amplification of the complex input communication signal.
